(19) United States
(12) Patent Application Publication
(10) Pub. No.: US 2012/0242382 A1
(43) Pub. Date: Sep. 27, 2012

(54) PHASE ADJUSTER AND SEMICONDUCTOR APPARATUS

(75) Inventors: Shigehiro Tsuchiya, Tokyo (JP); Hidemi Izumiyama, Kawasaki-Shi (JP); Noriaki Dobashi, Yokohama-Shi (JP)

(73) Assignee: KABUSHIKI KAISHA TOSHIBA, Tokyo (JP)

(21) Appl. No.: 13/237,062

(22) Filed: Sep. 20, 2011

(30) Foreign Application Priority Data
Mar. 25, 2011 (JP) 2011-068698

(51) Int. Cl. H03L 7/00

(52) U.S. Cl. 327/153

(57) ABSTRACT

According to one embodiment, a phase adjuster operates according to a phase difference between a first clock signal and a second clock signal. The adjuster includes an adjustment driving element and a crosstalk driving element. The adjustment driving element drives an input signal and generates an adjusted signal. The crosstalk driving element generates an in-phase and/or a reverse-phase crosstalk signal in parallel to the adjusted signal when the phase difference occurs between the first clock signal and the second clock signal.

### CROSS REFERENCE TO RELATED APPLICATION(S)

This application is based upon and claims the benefit of priority from the prior Japanese Patent Application No. 2011-068698, filed on Mar. 25, 2011, the entire contents of which are incorporated herein by reference.

### FIELD

Embodiments described herein relate generally to a phase adjuster and a semiconductor apparatus.

### BACKGROUND

In devices such as a Synchronous Dynamic Random Access Memory (SDRAM) provided with a parallel interface, in order to synchronize a plurality of signals operate with a clock signal or a strobe signal, it is necessary to perform inter-bit skew adjustment and phase adjustment between a clock or a strobe signal and a data signal.

In general, the skew adjustment and the phase adjustment are performed in the design process by using simulation software such as Simulation Program with Integrated Circuit Emphasis (SPICE). However, in actual semiconductor circuits, a skew between bits and a phase difference between a clock or a strobe signal and a data signal are variable according to a manufacturing process, an operation voltage, and an operation temperature. In this regard, it is necessary to provide a module for implementing the skew adjustment and the phase adjustment in a semiconductor apparatus.

In general, a module for implementing the skew adjustment or phase adjustment is a delay lock loop (DLL) or a phase interpolator (PhI). However, the circuit sizes of the DLL and the PhI are large. As a consequence, the circuit scale of a semiconductor apparatus becomes also large.

### BRIEF DESCRIPTION OF THE DRAWINGS

FIG. 1 is a block diagram of the memory system 1 of the present embodiment.

FIG. 2 is a circuit diagram of the semiconductor apparatus 10 of the first embodiment.

FIG. 3 is a circuit diagram of first and second clock trees 13a and 13b, and clock synchronizers 15a and 15b of the first embodiment.

FIG. 4 is an explanation diagram of a phase comparator 14 of the first embodiment.

FIGS. 5 and 6 are circuit diagrams of the phase adjusters 12a and 12b of the first embodiment.

FIG. 7 is an explanation diagram of a crosstalk signal of the first embodiment.

FIG. 8 is a circuit diagram of the semiconductor apparatus 10 of the second embodiment.

FIG. 9 is a circuit diagram of the clock tree 13 of the first example of the second embodiment.

FIG. 10 is a circuit diagram of the clock tree 13 of the second example of the second embodiment.

FIG. 11 is a circuit diagram of the phase comparator 14 of the third embodiment.

FIGS. 12 and 13 are circuit diagrams of the phase adjuster 12 of the third embodiment.

FIG. 14 is an explanation diagram of the crosstalk signal of the first embodiment.

FIGS. 15 to 17 are explanation diagrams of the operation of the phase comparator 14 of the third embodiment.

### DETAILED DESCRIPTION

Embodiments will now be explained with reference to the accompanying drawings.

In general, according to one embodiment, a phase adjuster operates according to a phase difference between a first clock signal and a second clock signal. The adjuster includes an adjustment driving element and a crosstalk driving element. The adjustment driving element drives an input signal and generates an adjusted signal. The crosstalk driving element generates an in-phase and/or a reverse-phase crosstalk signal in parallel to the adjusted signal when the phase difference occurs between the first clock signal and the second clock signal.

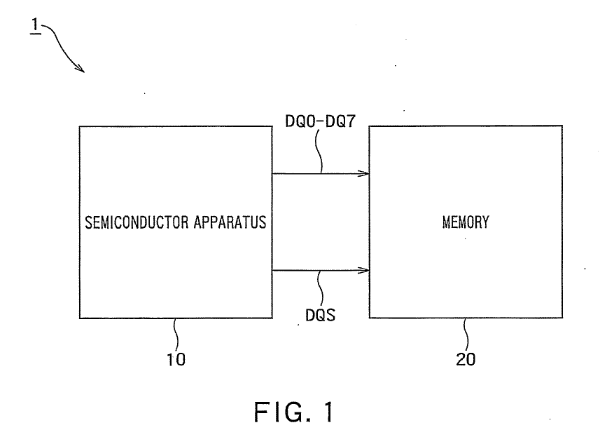

A memory system 1 of the present embodiment will be described. FIG. 1 is a block diagram of the memory system 1 of the present embodiment.

As illustrated in FIG. 1, the memory system 1 includes a semiconductor apparatus 10 and a memory 20. An interface between the semiconductor apparatus 10 and the memory 20 is a parallel interface. The memory 20, for example, is a SDRAM.

The semiconductor apparatus 10 is a physical layer semiconductor circuit which controls the memory 20. In detail, the semiconductor apparatus 10 outputs data signals DQ0 to DQ7 and a data strobe signal DQS to the memory 20. Data is stored in the memory 20 in synchronization with the data signals DQ0 to DQ7 and the data strobe signal DQS.

In addition, the number of the data signals DQ of the present embodiment is not limited to 8. Furthermore, the semiconductor apparatus 10 may control a memory other than a SDRAM, or a device which operates in synchronization with a plurality of clocks and is other than a memory.

Hereinafter, an embodiment of the semiconductor apparatus 10 will be described.

### First Embodiment

A first embodiment will be described. The first embodiment is an example in which the skew adjustment and the phase adjustment of an input signal of a clock tree are realized by using a crosstalk signal according to the phase difference between a plurality of clock signals.

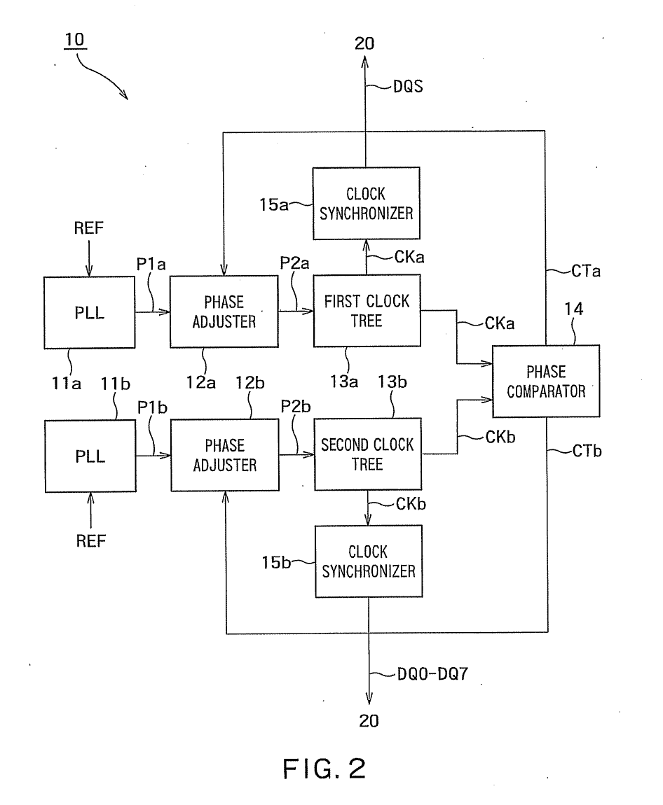

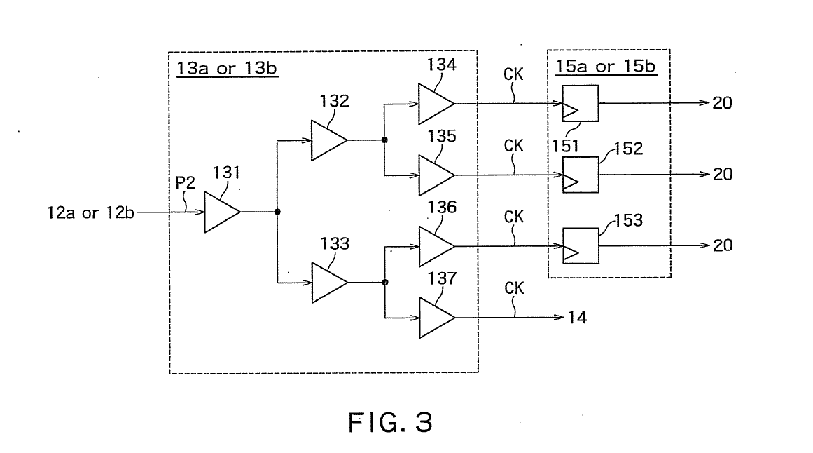

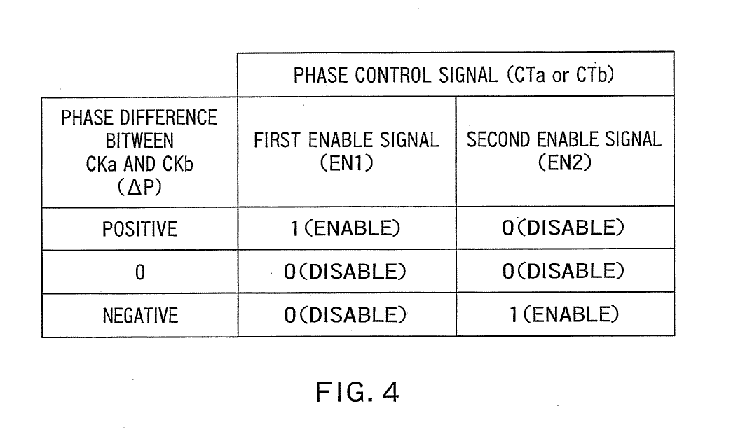

The semiconductor apparatus 10 of the first embodiment will be described. FIG. 2 is a circuit diagram of the semiconductor apparatus 10 of the first embodiment. FIG. 3 is a circuit diagram of first and second clock trees 13a and 13b, and clock synchronizers 15a and 15b of the first embodiment. FIG. 4 is an explanation diagram of a phase comparator 14 of the first embodiment.

As illustrated in FIG. 2, the semiconductor apparatus 10 includes phase look loops (PLLs) 11a and 11b, phase adjusters 12a and 12b, the first clock tree 13a, the second clock tree 13b, the phase comparator 14, and the clock synchronizers 15a and 15b.

The PLLs 11a and 11b generate phase signals P1a and P1b having the same phase as that of a reference signal REF, respectively. The phase signals P1a and P1b are signals to be subject to phase adjustment.

The phase adjusters 12a and 12b adjust the phases of the phase signals P1a and P1b based on control signals CTa and CTb outputted by the phase comparator 14, generate adjusted phase signals P2a and P2b, and then output the adjusted phase signals P2a and P2b to the first clock tree 13a and the second clock tree 13b, respectively.

The first clock tree 13a generates a first clock signal CKa from the adjusted phase signal P2a. The second clock tree 13b generates a second clock signal CKb from the adjusted phase signal P2b. A clock tree system of the first clock tree 13a is different from a clock tree system of the second clock tree 13b. Thus, the first clock signal CKa is different from the second clock signal CKb. As illustrated in FIG. 3, each of the first and second clock trees 13a and 13b includes a plurality of driving elements 131 to 137.

The phase comparator 14 compares the first clock signal CKa with the second clock signal CKb, and then generates the control signals CTa and CTb according to the phase difference ΔP between the first clock signal CKa and the second clock signal CKb. In more detail, the phase comparator 14 fixes one (for example, the control signal CTa) of the control signals, and then generates another (for example, the control signal CTb) of the control signals according to the phase difference ΔP. The fixed control signal (the control signal CTa) serves as a reference of the control signal (the control signal CTb) generated according to the phase difference ΔP. The control signals CTa and CTb include first and second enable signals EN1 and EN2, respectively, which will be described later.

As illustrated in FIG. 4, when the phase difference ΔP is a positive value (that is, when the phase of the first clock signal CKa is advanced than the phase of the second clock signal CKb), “1” is set in the first enable signal EN1 and “0” is set in the second enable signal EN2. Furthermore, when the phase difference ΔP is 0 (that is, when the phase of the first clock signal CKa is equal to the phase of the second clock signal CKb), “0” is set in the first and second enable signals EN1 and EN2. When the phase difference ΔP is a negative value (that is, when the phase of the first clock signal CKa is delayed than the phase of the second clock signal CKb), “0” is set in the first enable signal EN1 and “1” is set in the second enable signal EN2. Regarding the first and second enable signals EN1 and EN2, “1” indicates enable and “0” indicates disable.

The first clock synchronizer 15a is synchronized with the plurality of first clock signals CKa. The second clock synchronizer 15b is synchronized with a plurality of second clock signals CKb. As illustrated in FIG. 3, each of the first and second clock synchronizers 15a and 15b includes synchronization units 151 to 153 which synchronize the plurality of first and second clock signals CKa and CKb with each other.

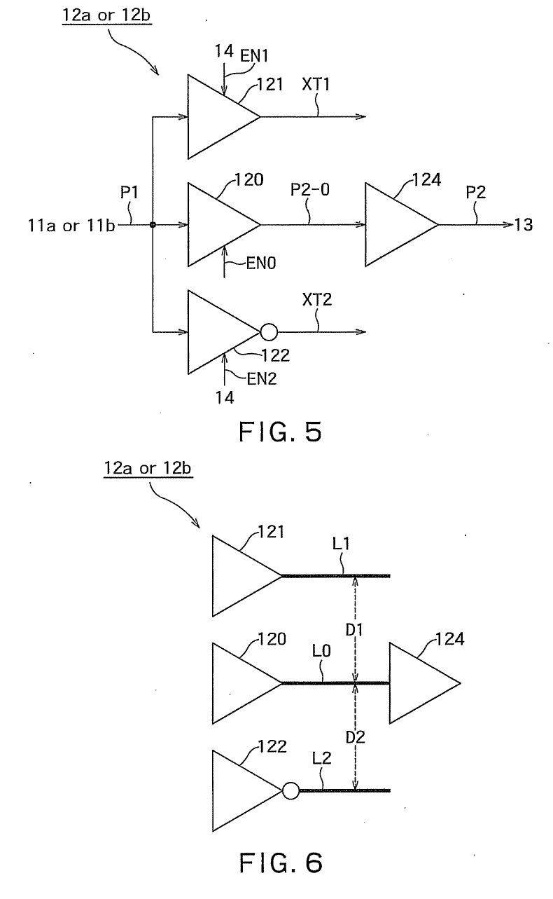

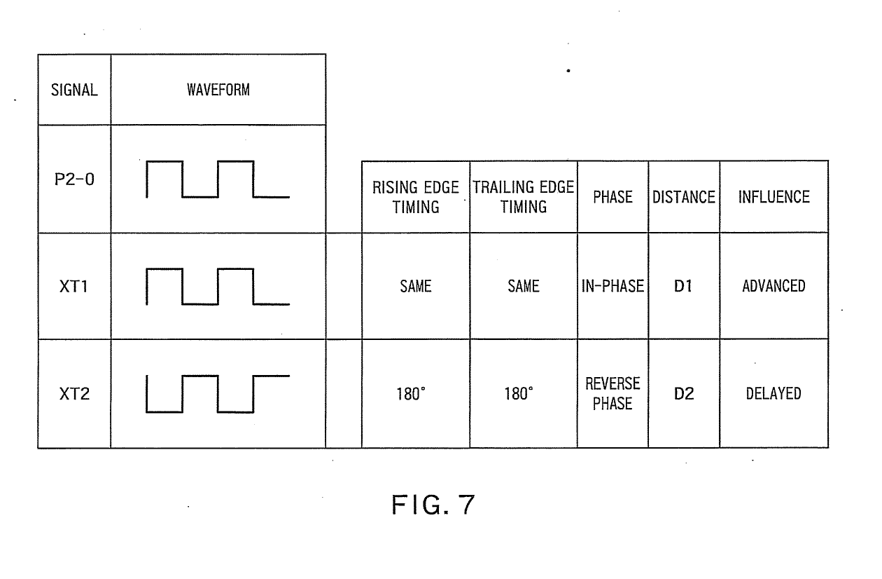

The phase adjusters 12a and 12b of the first embodiment will be described. FIGS. 5 and 6 are circuit diagrams of the phase adjusters 12a and 12b of the first embodiment. FIG. 7 is an explanation diagram of a crosstalk signal of the first embodiment.

As illustrated in FIG. 5, each of the phase adjusters 12a and 12b includes an adjustment driving element 120, crosstalk driving elements (a first crosstalk driving element 121 and a second crosstalk driving element 122), and a waveform shape driving element 124. These driving elements (the adjustment driving element 120, the first and second crosstalk driving elements 121 and 122, and the waveform shape driving element 124), for example, are tri-state buffers.

An enable signal EN0, in which “1” indicating enable has been set, is always supplied to the adjustment driving element 120. The adjustment driving element 120 drives a phase signal P1, and then generates an adjusted signal P2-0. The adjusted signal P2-0 is transmitted through a wiring L0 and is supplied to the waveform shape driving element 124 (see FIG. 6).

The first enable signal EN1 is supplied to the first crosstalk driving element 121. When “1” is set in the first enable signal EN1, the first crosstalk driving element 121 drives the phase signal P1, and then outputs a first crosstalk signal XT1 with the same phase as the adjusted signal P2-0. The drive capability of the first crosstalk driving element 121 is approximately the same as that of the adjustment driving element 120. The first crosstalk signal XT1 is transmitted through a first wiring L1. The first wiring L1 is spaced apart by a first distance D1 from the wiring L0 (see FIG. 6). The adjusted signal P2-0 is affected by the influence according to the distance D1 from the first crosstalk signal XT1, so that the phase of the adjusted signal P2-0 is advanced.

The second enable signal EN2 is supplied to the second crosstalk driving element 122. When “1” is set in the second enable signal EN2, the second crosstalk driving element 122 drives the phase signal P1, inverts the phase of the phase signal P1, and then outputs a second crosstalk signal XT2 with a phase inverse to the adjusted signal P2-0. The drive capability of the second crosstalk driving element 122 is approximately the same as that of the adjustment driving element 120. The second crosstalk signal XT2 is transmitted through a second wiring L2. The second wiring L2 is spaced apart by a second distance D2 from the wiring L0 (see FIG. 6). The adjusted signal P2-0 is affected by the influence according to the distance D2 from the second crosstalk signal XT2, so that the phase of the adjusted signal P2-0 is delayed.

That is, when the phase difference between the first clock signal CKa and the second clock signal CKb occurs, the first and second driving elements 121 and 122 generate the first and second crosstalk signals XT1 and XT2 with an in-phase and/or a reverse phase in parallel to the adjusted signal P2-0, respectively.

The waveform shape driving element 124 shapes the waveform of the adjusted signal P2-0 with a phase shifted by the influence of the first or second crosstalk signal XT1, or XT2, and then outputs a phase adjustment signal P2. In addition, the waveform shape driving element 124 may not be provided. In such a case, the phase adjustment signal P2 is the adjusted signal P2-0 with a phase shifted with respect to the phase signal P1 due to the influence of the first or second crosstalk signal XT1 or XT2.

As illustrated in FIG. 7, the adjusted signal P2-0 has a rectangular waveform which is the same as the phase signal P1.

The first crosstalk signal XT1 is equal to the adjusted signal P2-0. In detail, the first crosstalk signal XT1 is equal to the adjusted signal P2-0 in terms of a rising edge timing, a trailing edge timing, and a phase. That is, the first crosstalk driving element 121 generates an in-phase signal with respect to the adjusted signal P2-0 by using approximately the same drive capability as the adjustment driving element 120.

The second crosstalk signal XT2 is different from the adjusted signal P2-0. In detail, the rising edge timing of the second crosstalk signal XT2 coincides with the trailing edge timing of the adjusted signal P2-0, and the trailing edge timing of the second crosstalk signal XT2 coincides with the rising edge timing of the adjusted signal P2-0. That is, the phase of the second crosstalk signal XT2 is shifted relative to the phase of the adjusted signal P2-0 by 180°. In other words, the second crosstalk driving element 122 has drive capability which is approximately the same as the adjustment driving element 120, and generates a reverse phase signal with respect to the adjusted signal P2-0.

As described above, when “1” is set in the first enable signal EN1, the first crosstalk driving element 121 generates the first crosstalk signal XT1. Meanwhile, when “1” is set in the second enable signal EN2, the second crosstalk driving element 122 generates the second crosstalk signal XT2. When the adjusted signal P2-0 is affected by the influence of the first crosstalk signal XT1, the phase of the adjusted signal P2-0 is advanced. When the adjusted signal P2-0 is affected by the influence of the second crosstalk signal XT2, the phase of the adjusted signal P2-0 is delayed. That is, the first and second driving elements 121 and 122 change the timing of the adjusted signal P2-0 according to the phase difference ΔP between the first clock signal CKa and the second clock signal CKb. In addition, in the semiconductor apparatus 10, since a capacitance component is sufficiently larger than an inductor component, the displacement of a phase occurs due to the first crosstalk signal XT1 and the second crosstalk signal XT2. In addition, when “0” is set in the first and second enable signals EN1 and EN2, the first crosstalk driving element 121 and the second crosstalk driving element 122 are in a high impedance (Hi-Z) state. No case occurs in which “1” is simultaneously set in the first enable signal EN1 and the second enable signal EN2. When “1” is set in one of the first enable signal EN1 and the second enable signal EN2, “0” is set in the other one. Therefore, no case occurs in which the first crosstalk signal XT1 and the second crosstalk signal XT2 are simultaneously output.

According to the first embodiment, the phase adjusters 12a and 12b generate the first clock signal CKa and the second clock signal CKb, respectively, while adjusting the phase according to the phase difference AR The phase adjusters 12a and 12b include a driving element having a small circuit size as compared with a DLL and a PhI. Consequently, it is possible to realize skew adjustment and phase adjustment without an increase in a circuit size. Incidentally, the first embodiment can be realized by the only first crosstalk driving element 121 or the only second crosstalk driving element 122, which is provided in parallel to the adjustment driving element 120.

### Second Embodiment

A second embodiment will be described. The second embodiment is an example in which the phase adjusters 12a and 12b are provided in a clock tree 13. In addition, description the same as the above-mentioned embodiment will not be repeated.

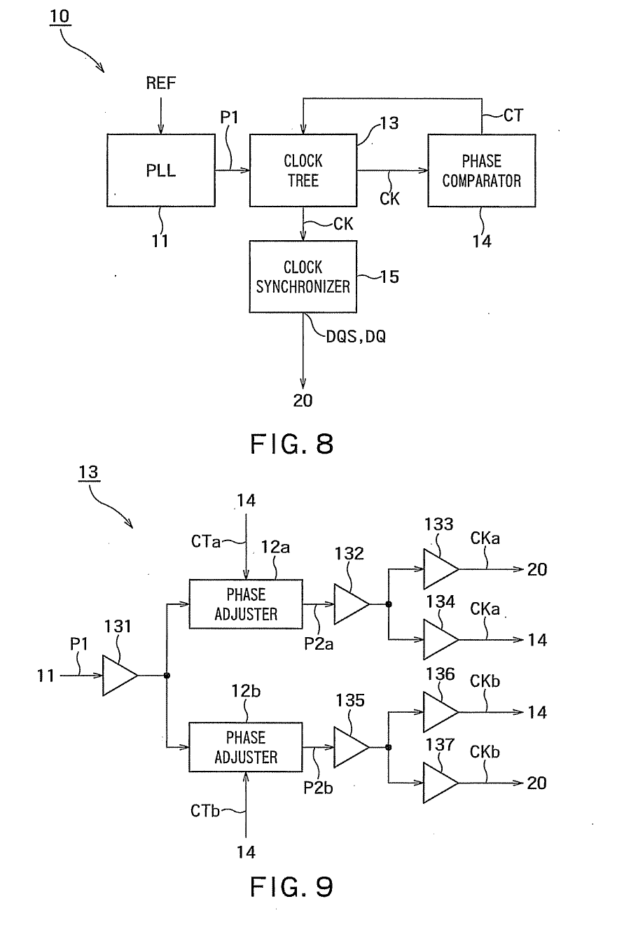

The semiconductor apparatus 10 of the second embodiment will be described. FIG. 8 is a circuit diagram of the semiconductor apparatus 10 of the second embodiment.

As illustrated in FIG. 8, the semiconductor apparatus 10 includes a PLL 11, the clock tree 13, a phase comparator 14, and a clock synchronizer 15. The PLL 11, the phase comparator 14, and the clock synchronizer 15 are the same as the first embodiment.

The clock tree 13 generates the first and second clock signals CKa and CKb from a phase signal P1. In the first embodiment, the phase adjusters 12a and 12b are provided outside the clock trees 13a and 13b, and the adjusted phase signals P2a and P2b outputted by the phase adjusters 12a and 12b are supplied to the clock trees 13a and 13b, respectively. However, in the second embodiment, the phase adjusters 12a and 12b are provided in the clock tree 13, and the phase signal P1 outputted by the PLL 11 is supplied to the clock tree 13.

A first example of the clock tree 13 of the second embodiment will be described. FIG. 9 is a circuit diagram of the clock tree 13 of the first example of the second embodiment.

As illustrated in FIG. 9, the clock tree 13 includes a plurality of driving elements 131 to 137, and the phase adjusters 12a and 12b.

The phase adjusters 12a and 12b adjust the phase of an output signal of the driving element 131 based on the control signals CTa and CTb outputted by the phase comparator 14, and then generate the adjusted phase signals P2a and P2b, respectively. The driving element 131 drives the phase signal P1, and then outputs the phase signal P1 to the phase adjusters 12a and 12b.

The driving elements 132 to 134 generate the first clock signal CKa from the adjusted phase signal P2a. The driving elements 135 to 137 generate the second clock signal CKb from the adjusted phase signal P2b. Actually, delay occurs due to a driving element or a wiring, thereby causing an error between the driving elements 132 to 134 and the driving elements 135 to 137. Therefore, the first clock signal CKa is different from the second clock signal CKb.

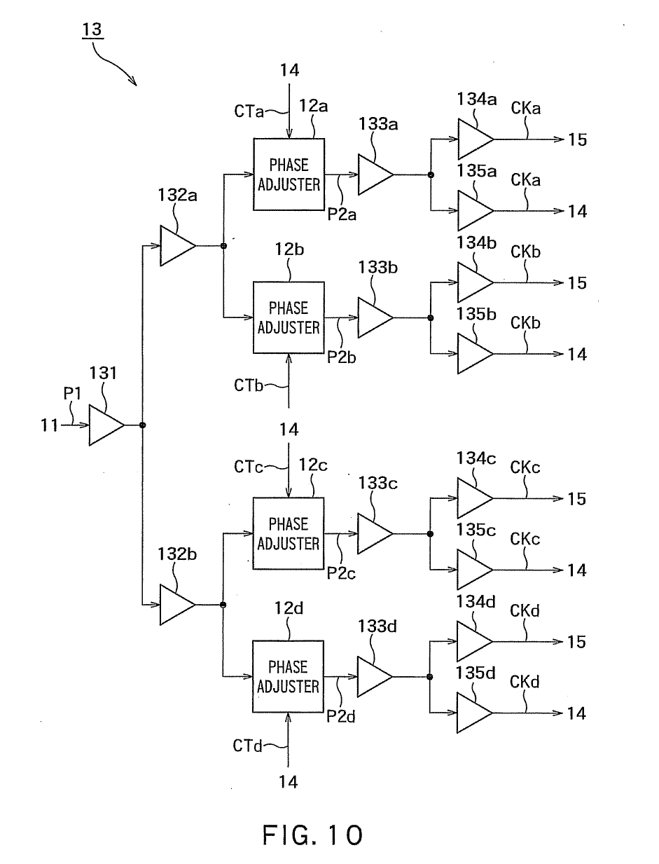

A second example of the clock tree 13 of the second embodiment will be described. FIG. 10 is a circuit diagram of the clock tree 13 of the second example of the second embodiment.

As illustrated in FIG. 10, the clock tree 13 includes a plurality of driving elements 131, 132a and 132b, 133a to 133d, 134a to 134d, and 135a to 135d, and a plurality of phase adjusters 12a to 12d.

The driving element 131 drives the phase signal P1 outputted by the PLL 11 by using a predetermined clock. The driving elements 132a and 132b drive an output signal of the driving element 131.

The phase adjusters 12a and 12b adjust the phase of an output signal of the driving element 132a based on control signals CTa and CTb outputted by the phase comparator 14, and then generate the adjusted phase signals P2a and P2b, respectively. The driving element 132a drives the phase signal P1. The output signal of the driving element 132a is inputted to the phase adjusters 12a and 12b.

Phase adjusters 12c and 12d adjust the phase of an output signal of the driving element 132b based on control signals CTc and CTd outputted by the phase comparator 14, and generate adjusted phase signals P2c and P2d, respectively. The driving element 132b drives the phase signal P1. The output signal of the driving element 132b is inputted to the phase adjusters 12c and 12d.

According to the second embodiment, the phase adjuster 12 is provided in the clock tree 13 and generates clock signal CK while adjusting the phase according to the phase difference ΔP. The phase adjuster 12 includes a driving element having a small circuit size as compared with a DLL and a PhI. Consequently, even when the phase adjuster 12 is provided in the clock tree 13, it is possible to achieve an effect the same as the first embodiment.

### Third Embodiment

A third embodiment will be described. The third embodiment is an example in which the phase adjuster 12 adjusts the phase of a signal according to the magnitude of the phase difference ΔP between the first clock signal CKa and the second clock signal CKb. In addition, description the same as the above-mentioned embodiments will not be repeated.

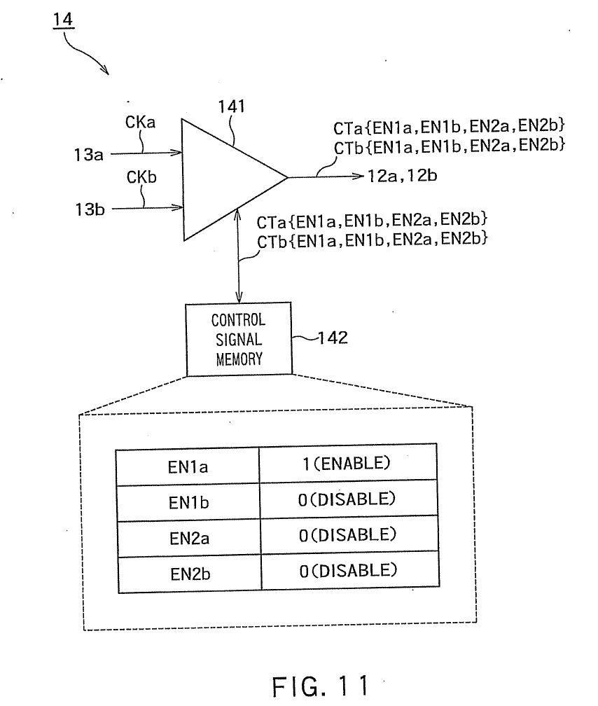

The phase comparator 14 of the third embodiment will be described. FIG. 11 is a circuit diagram of the phase comparator 14 of the third embodiment.

As illustrated in FIG. 11, the phase comparator 14 includes a comparator 141 and a control signal memory 142.

The comparator 141 compares the first clock signal CKa with the second clock signal CKb, and then generates the control signals CTa and CTb according to the phase difference ΔP between the first clock signal CKa and the second clock signal CKb. The control signals CTa and CTb include a plurality of first enable signals EN1a and EN1b, and a plurality of second enable signals EN2a and EN2b, respectively. The control signals CTa and CTb are outputted to the phase adjusters 12a and 12b, and then are stored in the control signal memory 142. That is, in the control signal memory 142, the control signals CTa and CTb generated immediately before are stored.

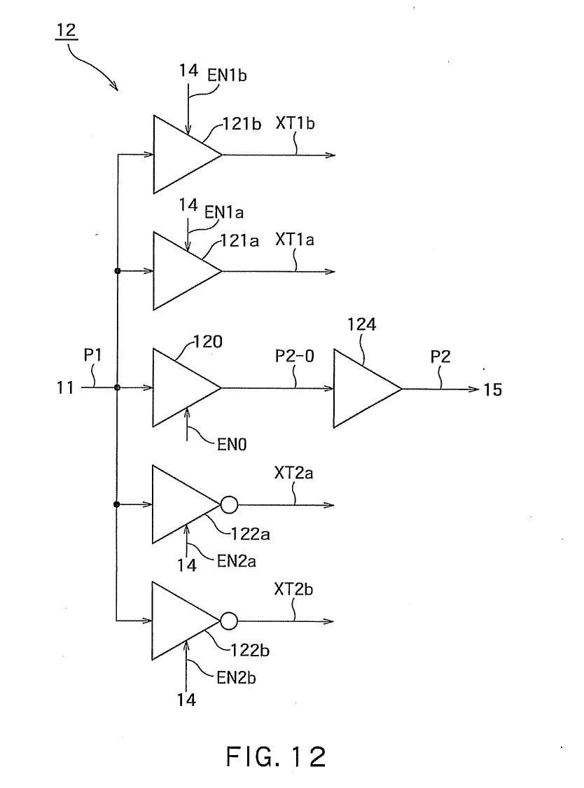

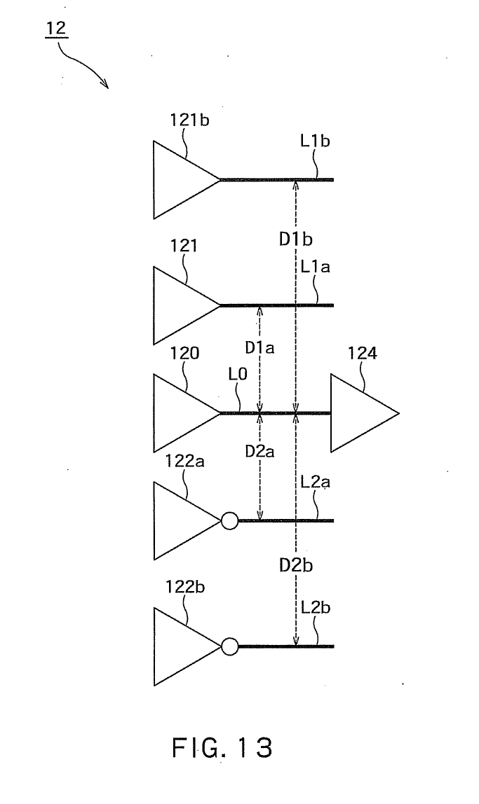

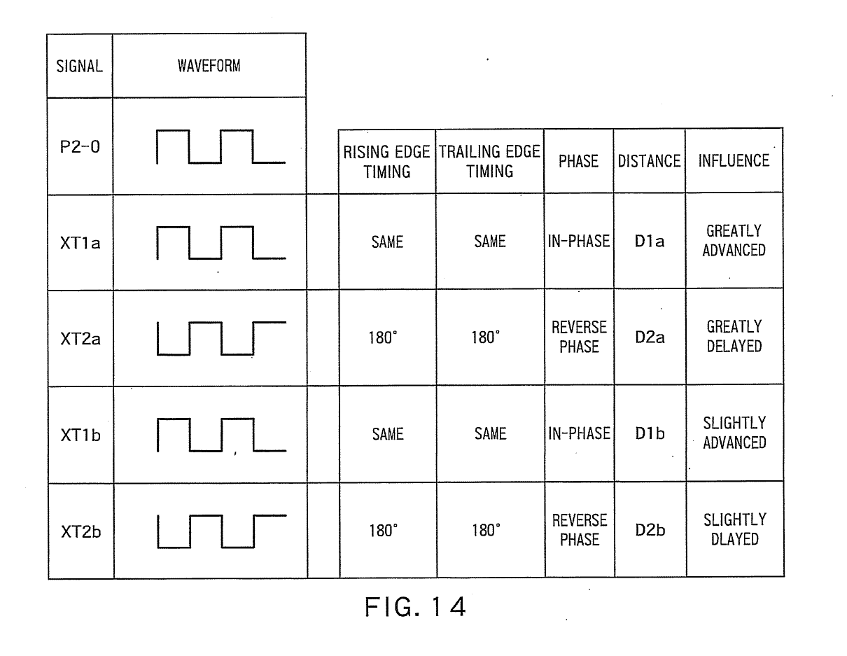

The phase adjuster 12 of the third embodiment will be described. FIGS. 12 and 13 are circuit diagrams of the phase adjuster 12 of the third embodiment. FIG. 14 is an explanation diagram of the crosstalk signal of the first embodiment.

As illustrated in FIG. 12, the phase adjuster 12 includes a adjustment driving element 120, a plurality of first driving elements 121a and 121b, a plurality of second driving elements 122a and 122b, and a waveform shape driving element 124. These driving elements, for example, are tri-state buffers. In addition, the adjustment driving element 120 and the waveform shape driving element 124 are the same as the first embodiment.

The first enable signals EN1a and EN1b are supplied to the plurality of first driving elements 121a and 121b, respectively. When “1” is set in the first enable signals EN1a and EN1b, the first driving elements 121a and 121b drive the phase signal P1 to generate first crosstalk signals XT1a and XT1b, respectively. The drive capabilities of the first driving elements 121a and 121b are approximately the same as the adjustment driving element 120. The first crosstalk signals XT1a and XT1b are transmitted through first wirings L1a and L1b, respectively. The first wiring L1a is spaced apart from the wiring L0 by a first distance D1a, and the first wiring L1b is spaced apart from the wiring L0 by a second distance D1b (see FIG. 13). The adjusted signal P2-0 is affected by the influence according to the first distance D1a and the second distance D1b from the first crosstalk signals XT1a and XT1b, so that the phase of the adjusted signal P2-0 is advanced, respectively. Since the first distance D1a is shorter than the second distance D1b, the influence of the first crosstalk signal XT1a to the adjusted signal P2-0 is larger than that of the first crosstalk signal XT1b to the adjusted signal P2-0.

The second enable signals EN2a and EN2b are supplied to the plurality of second driving elements 122a and 122b, respectively. When “1” is set in the second enable signals EN2a and EN2b, the second driving elements 122a and 122b drive the phase signal P1, invert the phase of the phase signal P1, and then generate second crosstalk signals XT2a and XT2b. The drive capabilities of the second driving elements 122a and 122b are approximately the same as that of the adjustment driving element 120. The second crosstalk signals XT2a and XT2b are transmitted through second wirings L2a and L2b, respectively. The second wiring L2a is spaced apart from the wiring L0 by a third distance D2a, and the second wiring L2b is spaced apart from the wiring L0 by a forth distance D2b (see FIG. 13). The adjusted signal P2-0 is affected by the influence according to the third distance D2a and the forth distance D2b from the second crosstalk signals XT2a and XT2b, so that the phase of the adjusted signal P2-0 is delayed. Since the third distance D2a is shorter than the force distance D2b, the influence of the second crosstalk signal XT2a to the adjusted signal P2-0 is larger than that of the second crosstalk signal XT2b to the adjusted signal P2-0.

As illustrated in FIG. 14, the adjusted signal P2-0 has a rectangular waveform which is the same as the phase signal P1.

The first crosstalk signals XT1a and XT1b are equal to the adjusted signal P2-0. In detail, the first crosstalk signals XT1a and XT1b are equal to the adjusted signal P2-0 in terms of a rising edge timing, a trailing edge timing, and a phase. That is, the first driving elements 121a and 121b generate an in-phase signal with respect to the adjusted signal P2-0 by using approximately the same drive capability as the adjustment driving element 120. However, as described above, since the first distance D1a is shorter than the second distance D1b, the phase of the adjusted signal P2-0 is greatly advanced when it receives the influence of the first crosstalk signal XT1a, and is slightly advanced when it receives the influence of the first crosstalk signal XT1b.

The second crosstalk signals XT2a and XT2b are different from the adjusted signal P2-0. In detail, the rising edge timings of the second crosstalk signals XT2a and XT2 coincide with the trailing edge timing of the adjusted signal P2-0, and the trailing edge timings of the second crosstalk signals XT2a and XT2b coincide with the rising edge timing of the adjusted signal P2-0. The phases of the second crosstalk signals XT2a and XT2b are shifted relative to the phase of the adjusted signal P2-0 by 180°. That is, the second driving elements 122a and 122b generate reverse phase signals with respect to the adjusted signal P2-0 by using approximately the same drive capability as the adjustment driving element 120. However, as described above, since the third distance D2a is shorter than the forth distance D2b, the phase of the adjusted signal P2-0 is greatly delayed if it receives the influence of the second crosstalk signal XT2a, and is slightly delayed if it receives the influence of the second crosstalk signal XT2b.

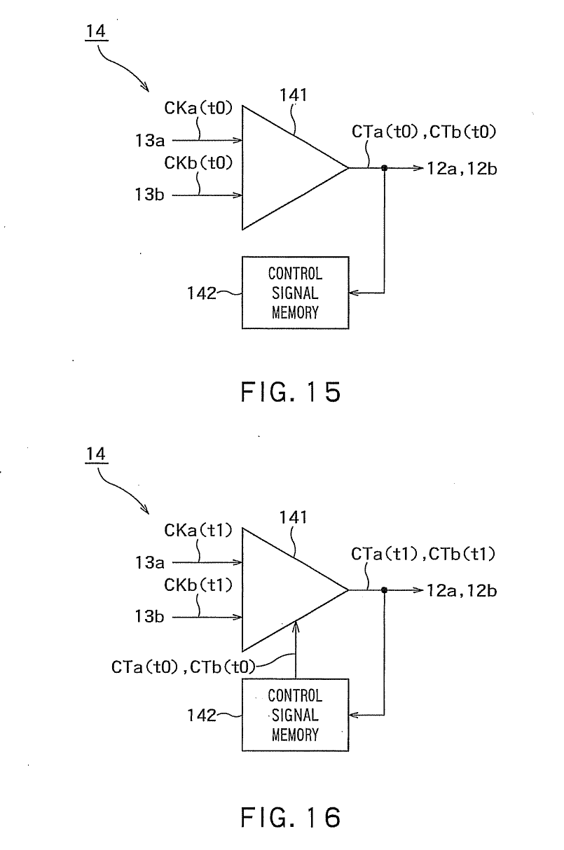

The operation of the phase comparator 14 of the third embodiment will be described. FIGS. 15 to 17 are explanation diagrams of the operation of the phase comparator 14 of the third embodiment.

First, at the time T0 (an initial state) of FIG. 15, when first and second clock signals CKa (t0) and CKb (t0) are inputted, the comparator 141 generates control signals CTa (t0) and CTb (t0) according to the phase difference ΔP (t0) between the first and second clock signals CKa (t0) and CKb (t0). The control signals CTa (t0) and CTb (t0) at the time T0 are outputted to the phase adjusters 12a and 12b while being transmitted to the control signal memory 142. In this way, the control signals CTa (t0) and CTb (t0) at the time T0 are stored in the control signal memory 142. In addition, in the initial state, since the control signal memory 142 is empty, the comparator 141 generates the control signals CTa (t0) and CTb (t0) without referring to information stored in the control signal memory 142.

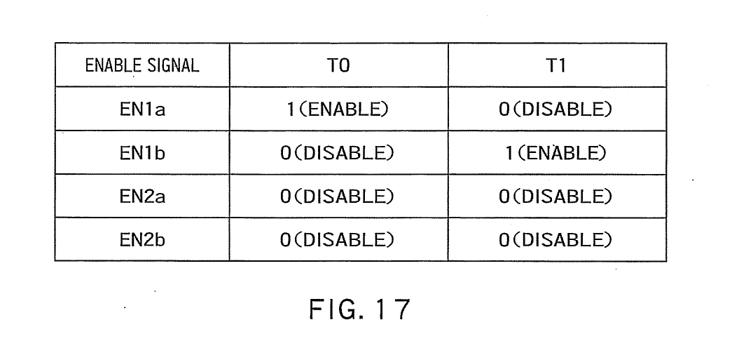

Next, at the time Ti of FIG. 16, when first and second clock signals CKa (t1) and CKb (t1) are inputted, the comparator 141 generates control signals CTa (t1) and CTb (t1) according to the phase difference ΔP (t1) between the first and second clock signals CKa (t1) and CKb (t1) at the time Ti with reference to the first and second clock signals CKa (t0) and CKb (t0) at the time T0 which are stored in the control signal memory 142. At this time, as illustrated in FIG. 17, when “1” is set only in the first enable signal EN1a at the time T0 and the phase difference ΔP (t1) is positive, the comparator 141 sets “1” in the first enable signal EN1b at the time T1 and sets “0” in the first enable signal EN1a and the second enable signals EN2a and EN2b at the time T0.

As described above, when the phase difference ΔP (t1) remains at the time T1 (in other words, when it is not possible to sufficiently reduce the phase difference ΔP only by the influence of the first crosstalk signal XT1a) even if the comparator 141 sets “1” in the first enable signal EN1a at the time T0, “1” is set in the first enable signal EN1b at the time Ti, which is different from one at the time T0. In this way, the first crosstalk signal XT1b, which is different from one at the time T0, has influence on the adjusted signal P2-0. Furthermore, as described above, the influence of the first crosstalk signal XT1b to the adjusted signal P2-0 is smaller than that of the first crosstalk signal XT1a to the adjusted signal P2-0. As a consequence, the phase of the adjusted signal P2-0 is greatly adjusted at the time T0, and is finely adjusted at the time T1.

So far, the third embodiment has described an example in which all the control signals CTa and CTb are stored in the control signal memory 142. However, the scope of the present invention is not limited thereto. Only an enable signal, in which “1” has been set, may be stored in the control signal memory 142. That is, the control signal memory 142 stores information for specifying a crosstalk signal having influence on an adjusted signal P2-0 immediately before.

According to the third embodiment, the phase adjusters 12a and 12b include the plurality of first driving elements 121a and 121b, and the plurality of second driving elements 122a and 122b, respectively. The phase comparator 14 generates the adjusted phase signal P2 while sequentially switching crosstalk signals having influence on the adjusted signal P2-0 according to the phase difference between the first clock signal CKa and the second clock signal CKb. In other word, the plurality of in-phase crosstalk signals to be outputted the plurality of first driving elements 121a and 121b are sequentially switched according to the phase difference between the first clock signal CKa and the second clock signal CKb. Also, the plurality of reverse-phase crosstalk signals to be outputted the plurality of second driving elements 122a and 122b are sequentially switched according to the phase difference between the first clock signal CKa and the second clock signal CKb. Consequently, in addition to the effect the same as the first embodiment, it is possible to further improve the accuracy of skew adjustment and phase adjustment as compared with the above-mentioned embodiments.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A phase adjuster configured to operate according to a phase difference between a first clock signal and a second clock signal, the adjuster comprising:
an adjustment driving element configured to drive an input signal and generate an adjusted signal; and
a crosstalk driving element configured to generate an in-phase and/or a reverse-phase crosstalk signal in parallel to the adjusted signal when the phase difference occurs between the first clock signal and the second clock signal.

2. The adjuster of claim 1, wherein the crosstalk driving element comprises a first crosstalk driving element configured to generate the in-phase crosstalk signal in parallel to the adjusted signal when a phase of the first clock signal is advanced as compared with a phase of the second clock signal.

3. The adjuster of claim 1, wherein the crosstalk driving element comprises a crosstalk second driving element configured to generate the reverse-phase crosstalk signal in parallel to the adjusted signal when a phase of the first clock signal is delayed as compared with a phase of the second clock signal.

4. The adjuster of claim 2, wherein the first crosstalk driving element is a tri-state buffer.

5. The adjuster of claim 3, wherein the second crosstalk driving element is a tri-state buffer.

6. The adjuster of claim 2, wherein
a plurality of first crosstalk driving elements is provided in parallel to the adjustment driving element and is connected to a plurality of first wirings set apart from a wiring connected to the adjustment driving element, by a different distance from each other, and
a plurality of in-phase crosstalk signals to be outputted from the first crosstalk driving elements is sequentially switched according to the phase difference.

7. The adjuster of claim 3, wherein
a plurality of second crosstalk driving elements is provided in parallel to the adjustment driving element and is connected to a plurality of second wirings set apart from a wiring connected to the adjustment driving element, by a different distance from each other, and
a plurality of reverse-phase crosstalk signals to be outputted from the second crosstalk driving elements is sequentially switched according to the phase difference.

8. The adjuster of claim 2, wherein drive capability of the first crosstalk driving element is approximately the same as drive capability of the adjustment driving element.

9. The adjuster of claim 3, wherein drive capability of the second crosstalk driving element is approximately the same as drive capability of the adjustment driving element.

10. A semiconductor apparatus comprising:
a clock tree configured to generate a first clock signal and a second clock signal;
a phase comparator configured to output an enable signal according to a phase difference between the first clock signal and the second clock signal; and
a phase adjuster configured to adjust a phase of an input signal based on the enable signal,
wherein the phase adjuster comprises:
an adjustment driving element configured to drive the input signal and generate an adjusted signal; and
a crosstalk driving element configured to generate an in-phase and/or a reverse-phase crosstalk signal in parallel to the adjusted signal when the phase difference occurs between the first clock signal and the second clock signal.

11. The apparatus of claim 10, wherein the crosstalk driving element comprises a first crosstalk driving element configured to generate the in-phase crosstalk signal in parallel to the adjusted signal when a phase of the first clock signal is advanced as compared with a phase of the second clock signal.

12. The apparatus of claim 10, wherein the crosstalk driving element comprises a second crosstalk driving element configured to generate the reverse-phase crosstalk signal in parallel to the adjusted signal when a phase of the first clock signal is delayed as compared with a phase of the second clock signal.

13. The apparatus of claim 11, wherein the first crosstalk driving element is a tri-state buffer.

14. The apparatus of claim 12, wherein the second crosstalk driving element is a tri-state buffer.

15. The apparatus of claim 11, wherein drive capability of the first crosstalk driving element is approximately the same as drive capability of the adjustment driving element.

16. The apparatus of claim 12, wherein drive capability of the second crosstalk driving element is approximately the same as drive capability of the adjustment driving element.

17. The apparatus of claim 10, wherein the phase adjuster is provided in the clock tree.

18. The apparatus of claim 11, wherein the phase adjuster comprises a plurality of the first crosstalk driving elements connected to a plurality of first wirings set apart from the adjustment driving element by different distances from each other, and
wherein the phase comparator sequentially switches a plurality of first crosstalk signals to be outputted from the first crosstalk driving elements according to the phase difference.

19. The apparatus of claim 12, wherein the phase adjuster comprises a plurality of the second crosstalk driving elements connected to a plurality of wirings set apart from the adjustment driving element by different distances from each other, and
wherein the phase comparator sequentially switches a plurality of second crosstalk signals to be outputted from the second crosstalk driving elements according to the phase difference.

20. The apparatus of claim 18, wherein the phase comparator comprises:
a comparator configured to compare the first clock signal with the second clock signal, and generate a control signal according to the phase difference between the first clock signal and the second clock signal; and
a control signal memory configured to store the control signal generated by the comparator,
wherein the comparator generates a control signal at a second time after a first time, making reference to the control signal at the first time, the control signal at the first time being stored in the control signal memory.
